(19) United States
(12) Patent Application Publication
(10) Pub. No.: US 2026/0064911 A1
(43) Pub. Date: Mar. 5, 2026

(54) DEVELOPER COMPOSITION FOR METAL-CONTAINING PHOTORESIST, AND METHOD OF FORMING PATTERNS INCLUDING DEVELOPING STEP USING THE COMPOSITION

(71) Applicant: SAMSUNG SDI CO., LTD., Yongin-si (KR)

(72) Inventors: Rosa SHIN, Suwon-si (KR); Hyungrang MOON, Suwon-si (KR); Seung HAN, Suwon-si (KR); Jongpil HO, Suwon-si (KR); Taeho KIM, Suwon-si (KR); Taeksoo KWAK, Suwon-si (KR); Gyeonghun PARK, Suwon-si (KR); Si-Kyun PARK, Suwon-si (KR); Eunyoung LIM, Suwon-si (KR); Jamin KU, Suwon-si (KR)

(21) Appl. No.: 19/319,522

(22) Filed: Sep. 4, 2025

(30) Foreign Application Priority Data
Sep. 5, 2024 (KR) 10-2024-0121007

(51) Int. Cl. G06F 30/25; G03F 7/16

(52) U.S. Cl. CPC G06F 30/25; G03F 7/168

(57) ABSTRACT

A developer composition for a metal-containing photoresist and a method of forming patterns including a developing step (e.g., act or task) utilizing the developer composition are disclosed. The developer composition for a metal-containing photoresist may be applied to a metal-containing photoresist having an exposed portion and an unexposed portion and include an organic solvent and an additive, wherein the exposed portion includes a metal oxide including a metal-oxygen-metal bond, and a metal oxide is substituted with a hydroxyl group at the terminal end, in an exposed portion, a ratio of the number of hydrogen bonds between the metal oxide including the metal-oxygen-metal bond and the organic solvent to the number of hydrogen bonds between the metal oxide including the metal-oxygen-metal bond and the additive is greater than 0 and less than or equal to about 4.5.

### CROSS-REFERENCE TO RELATED APPLICATION

The present application claims priority to and the benefit of Korean Patent Application No. 10-2024-0121007, filed on Sep. 5, 2024, in the Korean Intellectual Property Office, the entire content of which is incorporated herein by reference.

### BACKGROUND

### 1. Field

One or more embodiments of the present disclosure relate to a developer composition for a metal-containing photoresist and a method of forming patterns that includes a developing step (e.g., act or task) utilizing the developer composition.

### 2. Description of the Related Art

In recent years, the semiconductor industry has experienced a continuous reduction in critical dimensions. This trend has driven the need or desire for new high-performance photoresist materials and advanced patterning methods capable of supporting the fabrication of photoresist materials and patterning methods capable of supporting increasingly smaller features.

Related art chemically amplified (CA) photoresists are designed for high sensitivity. However, their typical elemental composition—often including oxygen (O), fluorine (F), sulfur(S), and carbon (C)—results in low absorbance at a wavelength of approximately (about) 13.5 nm, thereby reducing sensitivity under extreme ultraviolet (EUV) exposure. Additionally, CA photoresists tend to exhibit increased line edge roughness (LER) at smaller feature sizes, particularly due to the nature of acid-catalyzed processes, where LER increases as photospeed decreases. These limitations underscore the need for new types (kinds) of high-performance photoresists.

Accordingly, there is a need or desire for photoresist materials that offer improved etching resistance and resolution, while concurrently (simultaneously) enhancing sensitivity, critical dimension (CD) uniformity, and LER characteristics in photolithography processes.

### SUMMARY

One or more aspects of embodiments of the present disclosure are directed toward a developer composition for a metal-containing photoresist.

One or more aspects of embodiments of the present disclosure are directed toward a method of forming patterns including a developing step (e.g., act or task) utilizing the composition.

Additional aspects of embodiments will be set forth in part in the description which follows and, in part, will be apparent from the description or may be learned by practice of the presented embodiments of the disclosure.

A developer composition for a metal-containing photoresist according to one or more embodiments is a developer composition applied to a metal-containing photoresist having an exposed portion and an unexposed portion and includes an organic solvent and an additive,
wherein the exposed portion includes a metal oxide including a metal-oxygen-metal bond, and a metal oxide is substituted with a hydroxyl group at the terminal end (e.g., a metal oxide unit at the terminal end of the metal oxide is substituted with a hydroxyl group),
in the exposed portion, a ratio of the number of hydrogen bonds between the metal oxide containing the metal-oxygen-metal bond and the organic solvent to the number of hydrogen bonds between the metal oxide containing the metal-oxygen-metal bond and the additive is greater than 0 and less than or equal to 4.5,
a maximum probability distribution of the additive whose center of mass is within about 5 Å from the hydroxyl group of the metal oxide at the terminal end is greater than 0 and less than or equal to about 4,
the number of hydrogen bonds is calculated by counting each frame after molecular dynamics simulation and taking an average value of the each frame (e.g., the number of hydrogen bonds is determined by averaging the number of hydrogen bonds per frame over the course of a molecular dynamics simulation), and
the number of molecules is calculated using the radial distribution function:
molecular dynamics program: Materials Science Suites, Desmond module,
force field applied to calculations: OPLS3e, and
simulation condition: NVT simulation, 100 ns, 500 K, 1 atm.

For example, the number of hydrogen bonds is determined by performing a molecular dynamics simulation and averaging the number of hydrogen bonds per frame over the course of the simulation. The number of molecules is calculated utilizing a radial distribution function. The molecular dynamics simulation is performed using the Materials Science Suite, Desmond module. The force field applied in the simulation is OPLS3e. The simulation conditions include an NVT ensemble, a duration of 100 ns, a temperature of 500 K, and a pressure of 1 atm.

A method of forming patterns according to one or more embodiments includes coating a metal-containing photoresist composition on a substrate, performing a heat treatment to form a photoresist film on the substrate by drying and heating, exposing the metal-containing photoresist film, and developing utilizing the developer composition for the metal-containing photoresist.

The developer composition for the metal-containing photoresist according to one or more embodiments may have improved or optimized elements for a developer composition capable of minimizing or reducing the solubility of the photoresist in an exposed portion through simulation, and by applying a developer composition satisfying these elements, a photoresist pattern with minimized or reduced pattern collapse in the exposed portion may be implemented.

For example, the developer composition for the metal-containing photoresist may be formulated with enhanced components that are selected based on molecular simulation data. These components may be designed to minimize or reduce the solubility of the exposed portion of the photoresist during development. By tailoring the interaction between the developer and the metal oxide structures—through control of hydrogen bonding and spatial distribution of additives—the composition may effectively or suitably suppress or reduce dissolution in the exposed regions. This selective development behavior may contribute to the formation of well-defined patterns with reduced risk of pattern collapse. Such improvements are advantageous or beneficial in advanced lithography processes, including extreme ultraviolet (EUV) lithography, where high-resolution patterning and dimensional stability are important. The ability to engineer the developer composition at the molecular level enables enhanced control over development contrast, critical dimension (CD) uniformity, and line edge roughness (LER), thereby supporting the fabrication of next-generation semiconductor devices with increasingly smaller feature sizes.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1C are cross-sectional views illustrating a process sequence in order to describe a method of forming patterns.

FIG. 2 is a schematic view illustrating the distribution of the entire composition in which a metal oxide, an organic solvent, and an additive are placed in an exposed portion implemented for molecular dynamics calculations according to one or more embodiments of the present specification.

FIG. 3 is a schematic view of a model that induces distribution of additives and organic solvents onto the surface of a metal oxide according to the composition of FIG. 2.

FIG. 4 is a schematic view illustrating the distribution of a composition that has reached an equilibrium state by performing molecular dynamics simulation on the composition according to FIG. 3.

### DETAILED DESCRIPTION

Hereinafter, the subject matter of the present disclosure will be described in more detail with reference to the accompanying drawings. It should be understood that certain functions, structures, or processes that are well known to those of ordinary skill in the art may not be provided or simplified in the following description in order to more clearly illustrate the features of the present disclosure.

The utilization of “may” if (e.g., when) describing embodiments of the present disclosure refers to “one or more embodiments of the present disclosure.”

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In order to clearly illustrate the present disclosure, the description and relationships may not be provided, and throughout the disclosure, substantially the same or similar configuration elements may be designated by the same reference numerals. Also, because the size and thickness of each configuration illustrated in the drawing are arbitrarily shown for better understanding and ease of description, embodiments of the present disclosure are not necessarily limited thereto.

In the drawings, the thickness of layers, films, panels, regions, and/or the like may be exaggerated for clarity. In the drawings, the thickness of a part of layers, regions, and/or the like may be exaggerated for better understanding and ease of description.

It will be understood that if (e.g., when) an element, such as a layer, a film, a region, or a substrate, is referred to as being “on” or “above” another element, it may be directly on or directly above the other element or intervening elements may also be present therebetween. In contrast, if (e.g., when) an element is referred to as being “directly on” or “directly above” another element, there are no intervening elements present therebetween.

Hereinafter, a developer composition for a metal-containing photoresist according to one or more embodiments is described in more detail.

The developer composition for a metal-containing photoresist according to one or more embodiments may be a developer composition applied to a metal-containing photoresist having an exposed portion and an unexposed portion and may include an organic solvent and an additive.

The exposed portion may include a metal oxide including a metal-oxygen-metal bond, and a metal oxide may be substituted with a hydroxyl group at the terminal end (e.g., a metal oxide unit at the terminal end of the metal oxide may be substituted with a hydroxyl group),
in the exposed portion, the ratio of the number of hydrogen bonds between the metal oxide including the metal-oxygen-metal bond and the organic solvent to the number of hydrogen bonds between the metal oxide including the metal-oxygen-metal bond and the additive may be greater than 0 and less than or equal to about 4.5,
a maximum probability distribution of the additive whose center of mass is within about 5 Å from the hydroxyl group of the metal oxide at the terminal end may be greater than 0 and less than or equal to about 4,
the number of hydrogen bonds may be calculated by counting each frame after molecular dynamics simulation and taking an average value of the each frame (e.g., the number of hydrogen bonds may be determined by averaging the number of hydrogen bonds per frame over the course of a molecular dynamics simulation), and
the number of molecules may be calculated using the radial distribution function:
molecular dynamics program: Materials Science Suites, Desmond module,
force field applied to calculations: OPLS3e (OPLS3e refers to a version of the Optimized Potentials for Liquid Simulations (OPLS) force field. It may be used in molecular dynamics (MD) simulations to model the behavior of molecules by calculating the potential energy of a system based on atomic interactions), and
simulation condition: NVT simulation, 100 ns, 500 K, 1 atm (NPT simulation refers to a type (kind) of molecular dynamics (MD) simulation that maintains constant: N: Number of particles (atoms or molecules); P: Pressure; and T: Temperature. This is also known as the isothermal-isobaric ensemble).

This hydrogen bonding analysis provides a molecular-level understanding of how the developer composition interacts with the photoresist components, for example, in the unexposed regions. By quantifying the relative strengths and frequencies of hydrogen bonds among the metal compound, organic solvent, and additive, the formulation can be fine-tuned to achieve selective solubility. A higher number of hydrogen bonds between the metal compound and the organic solvent, compared to those with the additive, promotes dissolution of the unexposed portion without adversely affecting the exposed regions. This selective interaction is critical for achieving high-resolution pattern development, minimizing or reducing line edge roughness (LER), and ensuring uniform critical dimensions (CD) in advanced lithographic processes.

For example, the ratio of the number of hydrogen bonds between the metal oxide including the metal-oxygen-metal bond and the organic solvent to the number of hydrogen bonds between the metal oxide including the metal-oxygen-metal bond and the additive may be about 0.1 to about 4.5.

For example, the ratio of the number of hydrogen bonds between the metal oxide including the metal-oxygen-metal bond and the organic solvent to the number of hydrogen bonds between the metal oxide including the metal-oxygen-metal bond and the additive may be about 0.3 to about 4.5.

For example, the maximum probability distribution of the additive whose center of mass is within about 5 Å from the hydroxyl group of the metal oxide at the terminal end may be about 0.5 to about 3.

In one or more embodiments, the lower the interaction between the metal oxide including a metal-oxygen-metal bond and the additive and the organic solvent, and the lower a proportion of the additive distributed on the surface of the metal oxide substituted with the hydroxyl group at the terminal end, the lower the solubility of the exposed portion, thereby preventing pattern collapse (or reducing a degree or occurrence of pattern collapse).

For example, the metal oxide may include at least one metal selected from among tin (Sn), tellurium (Te), and antimony (Sb).

For example, the metal oxide may include a network containing SnOx (wherein x is an integer greater than 0).

Examples of an organic solvent included in a developer composition for a metal-containing photoresist according to one or more embodiments may include at least one selected from among an ether, an alcohol, a glycol ether, an aromatic hydrocarbon compound, a ketone, and an ester, but embodiments of the present disclosure are not limited thereto. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (or referred to as methyl isobutyl carbinol (MIBC)), hexanol, 1-methoxy-2-propanol, 1-ethoxy-2-propanol, ethylene glycol, propylene glycol, heptanone, propylene carbonate, butylene carbonate, toluene, xylene, methylethylketone, cyclopentanone, cyclohexanone, 2-hydroxy ethyl propionate, 2-hydroxy-2-methyl ethyl propionate, ethoxy ethyl acetate, hydroxy ethyl acetate, 2-hydroxy-3-methylmethyl butanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methyl methoxy propionate, ethyl ethoxy propionate, or a combination thereof, but embodiments of the present disclosure are not limited thereto.

Examples of the additive included in the developer composition for the metal-containing photoresist according to one or more embodiments may include an organic acid, phosphoric acid, phosphorous acid, a diol compound, and a diketone compound, but embodiments of the present disclosure are not limited thereto.

The developer composition for a metal-containing photoresist according to one or more embodiments may further include at least one other additive selected from among a surfactant, a dispersant, a hygroscopic agent, and a coupling agent.

In one or more embodiments, according to one or more embodiments, a method of forming patterns may include a developing step (e.g., act or task) utilizing the developer composition for a metal-containing photoresist as described in one or more embodiments. For example, the manufactured pattern may be a negative-type (kind) photoresist pattern.

A method for forming patterns according to one or more embodiments may include coating a metal-containing photoresist composition on a substrate, performing heat treatment in which a metal-containing photoresist film is formed on the substrate by drying and heating, exposing the metal-containing photoresist film, and developing utilizing the developer composition for the metal-containing photoresist. For example, the method may begin by applying a uniform (e.g., substantially uniform) layer of a metal-containing photoresist composition onto a substrate utilizing techniques, such as spin coating, slit coating, and/or inkjet printing. This may be followed by a soft bake or pre-bake step (e.g., act or task), during which the coated substrate is heated to remove residual solvent and promote adhesion of the photoresist film to the substrate surface. After the film is stabilized (formed), it may be exposed to a radiation source, such as EUV, e-beam, and/or deep ultraviolet (DUV) light, through a photomask or direct-write system to define the desired pattern. The exposed regions may undergo a chemical transformation, such as crosslinking, that alters their solubility. The substrate may be then subjected to a development step (e.g., act or task) utilizing the developer composition as described in one or more embodiments, which selectively dissolves the unexposed regions of the photoresist, thereby revealing the patterned features with high fidelity.

For example, the forming of the patterns utilizing the metal-containing photoresist composition may include coating a metal-containing photoresist composition on a substrate on which a thin film is formed by spin coating, slit coating, inkjet printing, and/or the like, and drying the coated metal-containing photoresist composition to form a resist layer. The metal-containing photoresist composition may include a tin-based compound, and for example, the tin-based compound may include at least one of an alkyl tin oxo group, an alkyl tin carboxyl group, and an alkyl tin hydroxyl group.

Subsequently, a first heat treatment process may be performed to heat the substrate on which the metal-containing photoresist film is formed. The first heat treatment process may be performed at a temperature of about 80° C. to about 120° C. In this process, the solvent is evaporated and the metal-containing photoresist film may be more firmly or suitably adhered to the substrate. For example, this first heat treatment may also be referred to as a soft bake or pre-bake and may serve one or more suitable functions in the patterning process. It may facilitate the controlled evaporation of residual solvents from the coated photoresist layer, which is to achieve uniform (e.g., substantially uniform) film thickness and preventing/reducing defects, such as bubbling and/or delamination, during subsequent processing. Also, this thermal step (e.g., act or task) may promote partial densification of the metal-containing photoresist, enhancing its mechanical stability and adhesion to the underlying substrate. The selected temperature range of about 80° C. to about 120° C. may be to ensure sufficient or suitable solvent removal without initiating premature chemical reactions or degradation of the photoresist components. This step (e.g., act or task) may be to ensure consistent exposure and development performance in later stages of the lithographic process

Then, the photoresist film may be selectively exposed.

Examples of light that may be utilized in the exposure process may include not only light having relatively low energy wavelengths, such as i-line (wavelength of 365 nm), KrF excimer laser (wavelength of 248 nm), and/or ArF excimer laser (wavelength of 193 nm), but also light having relatively high energy wavelengths, such as extreme ultraviolet (EUV, wavelength of 13.5 nm) and/or the like, and other courses, such as electron beam (e-beam) and/or the like.

For example, the light for exposure according to one or more embodiments may be light having a wavelength range of about 5 nm to about 150 nm, such as extreme ultraviolet (EUV, wavelength of 13.5 nm) and/or the like, and other sources, such as electron beam (e-beam).

In the step (e.g., act or task) of forming the photoresist pattern, a negative-type (kind) pattern may be formed.

The exposed portion of the photoresist film may form a polymer including a metal oxide containing a metal-oxygen-metal bond through a crosslinking reaction, such as condensation between organometallic compounds, and thus may have a different solubility from the unexposed portion of the photoresist film.

Then, a second heat treatment process may be performed on the substrate. The second heat treatment process may be performed at a temperature of about 90° C. to about 200° C. For example, the second heat treatment may also be referred to as a post-exposure bake (PEB) and may be a step (e.g., act or task) that follows the exposure of the metal-containing photoresist film. This thermal process may be conducted at a temperature ranging from about 90° C. to about 200° C., depending on the specific formulation of the photoresist and the desired patterning outcome. The primary function of the PEB may be to promote chemical reactions, such as crosslinking and/or condensation, within the exposed regions of the photoresist. These reactions may enhance the structural integrity and reduce the solubility of the exposed areas, thereby enabling the formation of a negative-tone pattern during development. The elevated temperature may accelerate the mobility of reactive species and facilitates the formation of a robust polymer network, for example, in metal-organic systems like tin-based photoresists. Proper control of the PEB conditions may be to achieve high-resolution features, minimizing/reducing line edge roughness (LER), and ensuring consistent critical dimension (CD) control across the substrate.

By performing the second heat treatment process, the exposed portion of the photoresist film becomes difficult to be dissolved in a developer.

For example, the photoresist pattern corresponding to the negative-type (kind) tone image may be completed by dissolving and then removing the photoresist film corresponding to the unexposed portion utilizing the photoresist developer as described in one or more embodiments.

As described in one or more embodiments, the photoresist pattern formed by exposure to not only light having relatively low energy wavelengths, such as i-line (wavelength of 365 nm), KrF excimer laser (wavelength of 248 nm), and/or ArF excimer laser (wavelength of 193 nm), but also light having relatively high energy wavelengths, such as extreme ultraviolet (EUV; wavelength of 13.5 nm) and/or the like, and other sources having high energy, such as an electron beam (e-beam), may have a thickness width of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In contrast, the photoresist pattern may have a pitch having a half-pitch of less than or equal to about 50 nm, for example, less than or equal to about 40 nm, for example, less than or equal to about 30 nm, for example, less than or equal to about 20 nm, for example, less than or equal to about 15 nm, and a line width roughness of less than or equal to about 10 nm, less than or equal to about 5 nm, less than or equal to about 3 nm, or less than or equal to about 2 nm.

The method as described herein may leverage the tailored hydrogen bonding interactions of the developer composition to achieve high-resolution pattern formation in metal-containing photoresists. By selectively dissolving the unexposed regions while preserving the integrity of the exposed, crosslinked areas, the developer composition enables precise pattern transfer with minimal or reduced line edge roughness (LER) and excellent or suitable critical dimension (CD) control. This may be advantageous or beneficial for next-generation lithographic techniques, such as EUV and e-beam lithography, where sub-20 nm features and tight process windows are required or desired. The ability to form patterns with half-pitches below about 30 nm and LER values under about 3 nm demonstrates the effectiveness of the developer composition in supporting advanced semiconductor manufacturing nodes.

Hereinafter, a method of forming patterns is described in more detail with reference to the drawings.

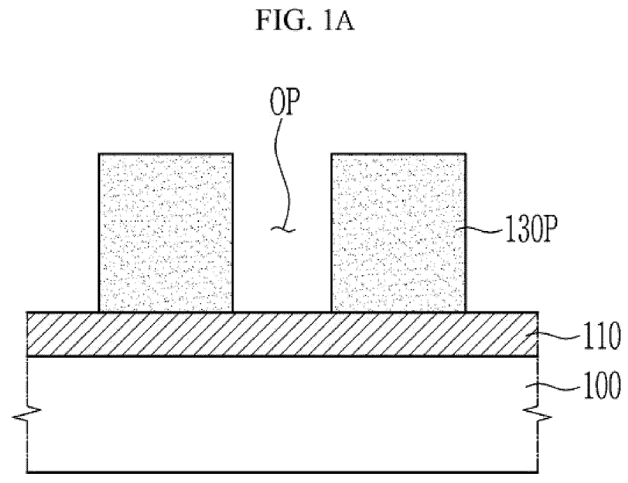

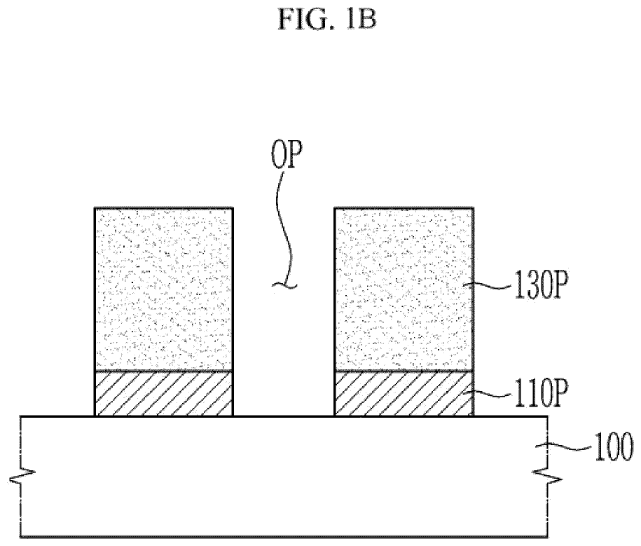

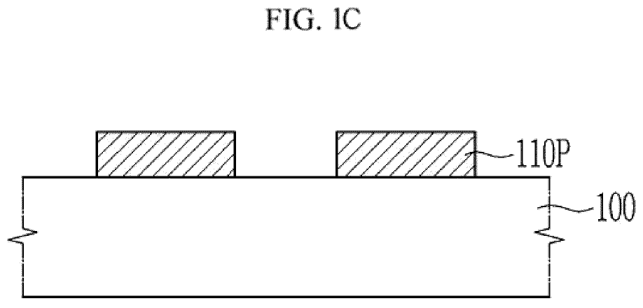

FIGS. 1A-1C are cross-sectional views illustrating a process sequence in order to describe a method of forming patterns.

Referring to FIG. 1A, the exposed photoresist film may be developed to form a photoresist pattern 130P.

In one or more embodiments, the exposed photoresist film may be developed to remove an unexposed portion of the photoresist film, and the photoresist pattern 130P including the exposed portion of the photoresist film may be formed. The photoresist pattern 130P may include a plurality of openings OP.

In one or more embodiments, the development of the photoresist film may be performed through a negative-tone development (NTD) process. Herein, the developer composition for the metal-containing photoresist according to one or more embodiments may be utilized as a developer composition.

Referring to FIG. 1B, the photoresist pattern 130P may be utilized to process a feature layer 110 in the result of FIG. 1A.

For example, the feature layer 110 may be processed through one or more suitable processes of etching a feature layer 110 exposed through the openings OP of the photoresist pattern 130P, injecting impurity ions into the feature layer 110, forming an additional film on the feature layer 110 through the openings OP, deforming a portion of the feature layer 110 through the openings OP, and/or the like. FIG. 1B illustrates an example process of processing a feature pattern 110P by etching the feature layer 110 exposed through the openings OP.

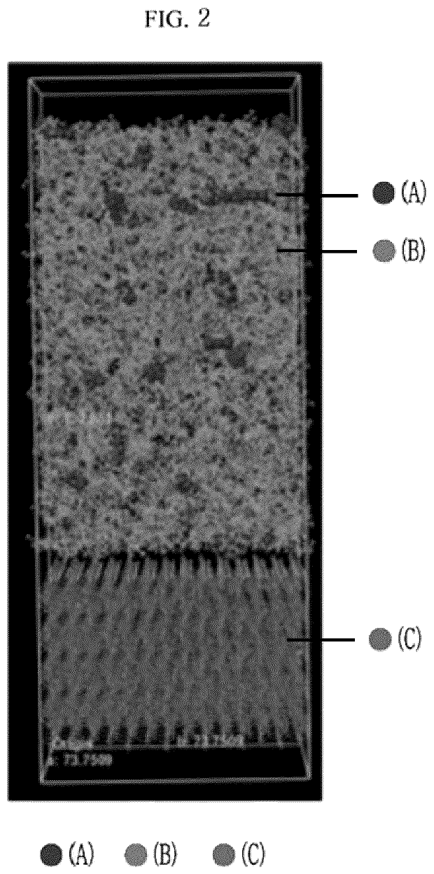

Referring to FIG. 1C, the photoresist pattern 130P remaining on the feature pattern 110P may be removed in the result of FIG. 2. In order to remove the photoresist pattern 130P, ashing and stripping processes may be used. The feature pattern 110P may be on a substrate 100.

Hereinafter, one or more embodiments of the present disclosure will be described in more detail through examples relating to the preparation of the developer composition for the metal-containing photoresist as described in one or more embodiments. However, embodiments of the present disclosure are not limited by the following examples.

The molecular dynamics simulation results data are shown in Table 1.

For molecular dynamics calculations, the Materials Science Suites program and Desmond module were used to produce initial compositions including organic solvents and additives, adjusting the number of additives and solvents according to additive conditions, so that (e.g., such that) the total number of molecules of the additive and organic solvent was 2000.

In one or more embodiments, the metal oxide may be a mimic structure for the SnOₓ (wherein x is an integer greater than 0) crystal implemented for molecular dynamics simulation. Because molecular dynamics calculations are not feasible for the SnOₓ crystal molecule due to the extended coordination number of Sn atoms, the SnOx crystal structure capable of molecular dynamics has been created by changing Si atoms to Sn atoms based on the SiO₂ cubic structure presented in the reference: M. D. Foster, O.D. Friedrichs, R. G. Bell, F. A. A. Paz, and J. Klinowski, “Chemical evaluation of hypothetical uninodal zeolites,” Journal of the American Chemical Society, 126:9769-9775, 2004, the entire content of which is incorporated herein by reference.

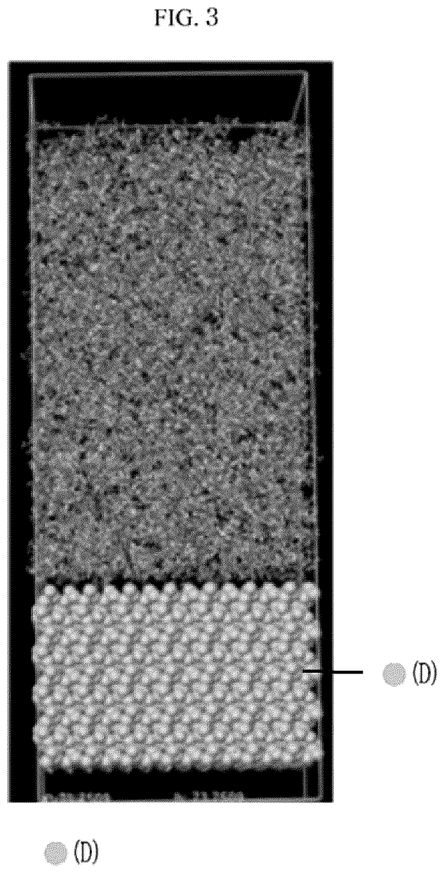

Schematic views of the compositions in which equilibrium has been completed for the initial compositions herein are shown in FIGS. 2 and 3.

FIG. 2 is a schematic view illustrating the distribution of the entire composition in which a metal oxide, an organic solvent, and an additive are placed in an exposed portion implemented for molecular dynamics calculations according to one or more embodiments of the present specification.

FIG. 3 is a schematic view of a model that induces distribution of additives and organic solvents onto the surface of a metal oxide according to the composition of FIG. 2.

Referring to FIG. 2, in the initial composition of the exposed portion, the additive (A) and the organic solvent (B) are randomly arranged on the SnOₓ crystal (C) structure, and

in FIG. 3, SnOₓ crystals are induced to the surface (D) by using the barrier potential.

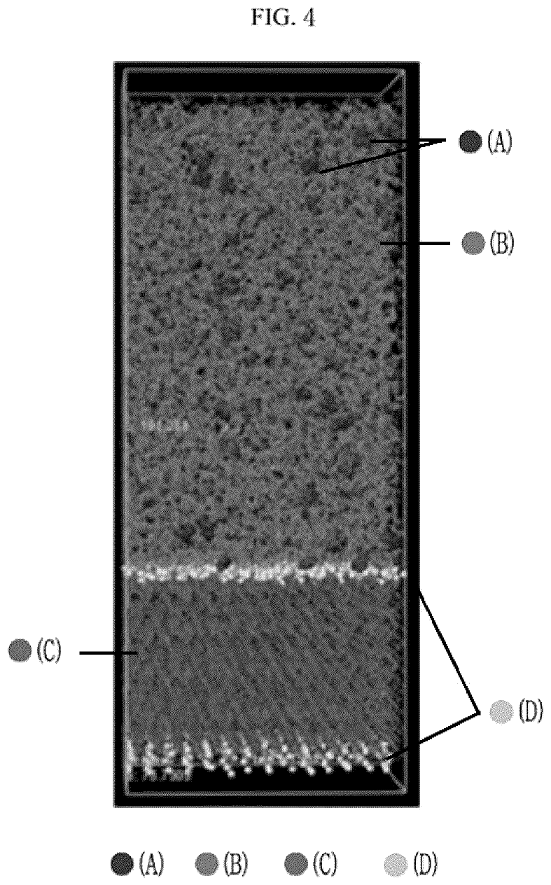

Next, the equilibrium state was calculated by performing molecular dynamics simulation for 100 ns under the conditions of NVT ensemble method (Thermostat method: Nose-Hoover chain), 1 atm, and 500 K. At this time, the distribution of the composition that reached equilibrium is shown in FIG. 4.

Referring to FIG. 4, in the composition in which the optimization of the exposed portion is completed, a certain (e.g., set or predetermined) level of distance is maintained between the SnOₓ (D) induced on the surface of the SnOₓ crystal (C) structure, the organic solvent (B), and the additive (A), so that (e.g., such that) dissolution by the developer is suppressed or reduced.

In one or more embodiments, the number of hydrogen bonds was calculated by counting the number of hydrogen bonds between the metal oxide, organic solvent, and additive in the entire cell frame by frame after molecular dynamics simulation and taking the average value of the values for each frame.

Also, the number of additive molecules on the SnOₓ surface (additive distribution) was calculated using the radial distribution function, which is the probability that the center of mass of the additive is distributed within about 5 Å from the surface hydroxyl groups of SnOₓ at the terminal end.

TABLE 1

| | Exposed portion | | The number of | | The number of | |
|---|---|---|---|---|---|---|
| | | Organic | simulations | | hydrogen bond | |
| | Additive | solvent | | Organic | Metal oxide | Metal oxide |
| | (wt %) | (wt %) | Additive | solvent | and additive | and solvent |
| Comparative | C1 | S1 | 35 | 1965 | 5.82 | 76.07 |
| Example 1 | (1) | (99) | | | | |
| Example 1 | C1 | S1 | 155 | 1845 | 24.6 | 67.8 |
| | (5) | (95) | | | | |
| Comparative | C1 | S1 | 300 | 1700 | 138.9 | 84.3 |
| Example 2 | (10) | (90) | | | | |
| Comparative | C2 | S1 | 25 | 1975 | 10.1 | 75.2 |
| Example 3 | (1) | (99) | | | | |
| Comparative | C3 | S1 | 20 | 1980 | 6.4 | 75.6 |
| Example 4 | (1) | (99) | | | | |
| Comparative | C4 | S2 | 80 | 1920 | 4.3 | 83.5 |
| Example 5 | (3) | (97) | | | | |
| Example 2 | C3 | S2 | 498 | 1502 | 24.5 | 65.3 |
| | (20) | (80) | | | | |
| Comparative | C3 | S1 | 80 | 1920 | 5.7 | 76.4 |
| Example 6 | (4) | (96) | | | | |
| Comparative | C3 | S3 | 200 | 1800 | 22.6 | 181.5 |
| Example 7 | (10) | (90) | | | | |
| Comparative | C5 | S1 | 150 | 1850 | 5.78 | 70.1 |
| Example 8 | (10) | (90) | | | | |
| Comparative | C5 | S2 | 354 | 1646 | 9.9 | 70.6 |
| Example 9 | (20) | (80) | | | | |
| Comparative | C6 | S1 | 13 | 1987 | 13.6 | 75.6 |
| Example 10 | (0.5) | (95.5) | | | | |
| Comparative | C8 | S3 | 20 | 1980 | 14.5 | 67.8 |
| Example 11 | (1) | (99) | | | | |
| Example 3 | C9 | S2 | 430 | 1570 | 20.4 | 65 |
| | (20) | (80) | | | | |
| Example 4 | C10 | S1 | 830 | 1170 | 160.7 | 47.3 |
| | (40) | (60) | | | | |
| Example 5 | C7 | S1 | 185 | 1815 | 23.9 | 62.9 |
| | (10) | (90) | | | | |

### Additive

C1: Propionic acid
C2: Succinic acid
C3: Fumaric acid
C4: Acetyl acetone
C5: Trifluoroacetylacetone
C6: Methylphosphonic acid
C7: Maltol
C8: Phosphorous acid
C9: Tropolone
C10: Catechol

### Organic Solvent

S1: n-Butyl acetate
S2: Propylene glycol methyl ether acetate (PGMEA)
S3: methyl isobutyl carbinol (MIBC)

### Evaluation: ArF Pattern Evaluation

An organometallic compound having the structure of the following chemical formula C was dissolved in 4-methyl-2-pentanol at a concentration of 1 wt %, and then filtered through a 0.1 μm polytetrafluoroethylene (PTFE) syringe filter to prepare a photoresist composition.

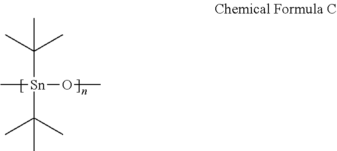

The prepared organic metal-containing photoresist (PR) composition was spin-coated on an 8-inch wafer at 1,500 rpm for 30 seconds, and then heat-treated at 110° C. for 60 seconds to produce a coated wafer.

The coated wafer was exposed to a 20 mJ to 35 mJ with a L/S pattern by using an ArF immersion exposure apparatus (Nikon Precision Inc.; NSR-S610C, NA=1.30, σ0.98/0.65, 35° dipole s-polarized illumination, 6% halftone phase shift mask), baked (PEB) at 100° C. for 60 seconds, developed by using each of the developer compositions according to Examples 1 to 5 and Comparative Examples 1 to 11 at a spin speed of 1500 rpm for 30 seconds, and cured at 240° C. for 60 seconds, obtaining a 1:1 line and space (L/S) pattern with a width of 40 nm. This pattern was examined with respect to a cross-section shape by using an electron microscope. A pattern collapse occurrence rate of the pattern was calculated according to Equation 1 to evaluate ArF pattern performance.

$$Pattern collapse occurance rate = {\{ ( number of collapsed patterns ) / ( total number of patterns ) \}}^{*} 100 ( \% ) \qquad Equation 1$$

### Evaluation Criteria

∘: pattern collapse occurrence rate <60%
X: pattern collapse occurrence rate ≥60%

TABLE 2

| | Hydrogen bond ratio | | | |
|---|---|---|---|---|
| | (Normalized) | | Additive | |
| | Metal oxide | Metal oxide | distribution | ArF pattern |
| | and additive | and solvent | g(R) | evaluation |
| Comparative | 1.0 | 13.1 | 1.93 | X |
| Example 1 | | | | |
| Example 1 | 1.0 | 2.8 | 2.26 | ◯ |
| Comparative | 1.0 | 0.6 | 4.53 | X |
| Example 2 | | | | |
| Comparative | 1.0 | 7.4 | 3.25 | X |
| Example 3 | | | | |
| Comparative | 1.0 | 11.8 | 2.38 | X |
| Example 4 | | | | |
| Comparative | 1.0 | 19.4 | 0.66 | X |
| Example 5 | | | | |
| Example 2 | 1.0 | 2.7 | 0.64 | ◯ |
| Comparative | 1.0 | 13.4 | 0.83 | X |
| Example 6 | | | | |
| Comparative | 1.0 | 8 | 0.93 | X |
| Example 7 | | | | |
| Comparative | 1.0 | 12.1 | 0.66 | X |
| Example 8 | | | | |
| Comparative | 1.0 | 7.1 | 0.53 | X |
| Example 9 | | | | |
| Comparative | 1.0 | 5.6 | 14.7 | X |
| Example 10 | | | | |
| Comparative | 1.0 | 4.7 | 1.16 | X |
| Example 11 | | | | |
| Example 3 | 1.0 | 3.2 | 0.79 | ◯ |
| Example 4 | 1.0 | 0.3 | 1.97 | ◯ |
| Example 5 | 1.0 | 2.6 | 0.68 | ◯ |

Referring to Table 2, when applying the developer compositions for the metal-containing photoresist according to Examples 1 to 5, the dissolution ability in the exposed portion is suppressed or reduced and pattern collapse is minimized or reduced compared to when applying the developer compositions for the metal-containing photoresist according to Comparative Examples 1 to 11.

A patterning device, a developer composition manufacturing device, and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the one or more suitable components of the device may be formed or arranged on one integrated circuit (IC) chip or on separate IC chips. Further, the one or more suitable components of the device may be implemented on a flexible printed circuit film, a tape carrier package (TCP), a printed circuit board (PCB) or formed or arranged on one substrate. Further, the one or more suitable components of the device may be a process or thread, running on one or more processors, in one or more computing devices, executing computer program instructions and interacting with other system components to perform the one or more suitable functionalities as described herein. The computer program instructions may be stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the present disclosure.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. Accordingly, the modified or transformed embodiments as such may not be understood separately from the technical ideas and aspects of embodiments of the present disclosure, and the modified embodiments may be within the scope of the appended claims and equivalents thereof of the present disclosure.

### REFERENCE NUMERALS

| | |
|---|---|
| 100: substrate | OP: opening |
| 110: feature layer | 110P: feature pattern |
| 130P: photoresist pattern | |

What is claimed is:

1. A developer composition, comprising:
an organic solvent; and
an additive,
wherein:
the developer composition is to be applied to a metal-containing photoresist having an exposed portion and an unexposed portion;
the exposed portion comprises a metal oxide, the metal oxide comprising a metal-oxygen-metal bond; and
a metal oxide unit at the terminal end of the metal oxide is substituted with a hydroxyl group,
wherein, in the exposed portion:
a ratio of the number of hydrogen bonds between the metal oxide comprising the metal-oxygen-metal bond and the organic solvent to the number of hydrogen bonds between the metal oxide comprising the metal-oxygen-metal bond and the additive is greater than 0 and less than or equal to 4.5;
a maximum probability distribution of the additive whose center of mass is within 5 Å from the hydroxyl group of the metal oxide at the terminal end is greater than 0 and less than or equal to 4; and
the number of hydrogen bonds is determined by averaging the number of hydrogen bonds per frame over the course of a molecular dynamics simulation, and
wherein the developer composition is a developer composition for a metal-containing photoresist.

2. The developer composition as claimed in claim 1, wherein:
the ratio of the number of hydrogen bonds between the metal oxide comprising the metal-oxygen-metal bond and the organic solvent to the number of hydrogen bonds between the metal oxide comprising the metal-oxygen-metal bond and the additive is 0.1 to 4.5.

3. The developer composition as claimed in claim 1, wherein:
the ratio of the number of hydrogen bonds between the metal oxide comprising the metal-oxygen-metal bond and the organic solvent to the number of hydrogen bonds between the metal oxide comprising the metal-oxygen-metal bond and the additive is 0.3 to 4.5.

4. The developer composition as claimed in claim 1, wherein:
the maximum probability distribution of the additive whose center of mass is within 5 Å from the hydroxyl group of the metal oxide at the terminal end is 0.5 to 3.

5. The developer composition as claimed in claim 1, wherein:
the metal oxide comprises at least one metal selected from among Sn, Te, Sb, and combinations thereof.

6. The developer composition as claimed in claim 1, wherein:
the metal oxide comprises a network comprising SnOₓ, x being an integer of greater than 0.

7. The developer composition as claimed in claim 1, wherein:
the organic solvent comprises at least one selected from among an ether, an alcohol, a glycol ether, an aromatic hydrocarbon compound, a ketone, an ester, and combinations thereof.

8. The developer composition as claimed in claim 1, wherein:
the organic solvent comprises at least one selected from among n-butyl acetate, propylene glycol methyl ether acetate (PGMEA), methyl isobutyl carbinol (MIBC), and combinations thereof.

9. The developer composition as claimed in claim 1, wherein:
the additive comprises at least one selected from among an organic acid, phosphoric acid, phosphorous acid, a diol compound, a diketone compound, and combinations thereof.

10. The developer composition as claimed in claim 1, wherein:
the additive comprises at least one selected from among propionic acid, succinic acid, fumaric acid, acetyl acetone, trifluoroacetylacetone, methylphosphonic acid, maltol, phosphorous acid, tropolone, catechol, and combinations thereof.

11. The developer composition as claimed in claim 1, further comprising at least one other additive selected from among a surfactant, a dispersant, a hygroscopic agent, a coupling agent, and combinations thereof.

12. The developer composition as claimed in claim 1, wherein the number of hydrogen bonds is determined based on the molecular dynamics simulation performed with:
a molecular dynamics program comprising the Desmond module of the Materials Science Suite;
a force field comprising OPLS3e; and
a simulation conditions comprising an NPT ensemble, a simulation time of 100 nanoseconds, a temperature of 500 K, and a pressure of 1 atm.

13. A method comprising:
coating a metal-containing photoresist composition on a substrate;
performing heat treatment in which a metal-containing photoresist film is on the substrate by drying and heating;
exposing the metal-containing photoresist film; and
developing utilizing the developer composition as claimed in claim 1,
wherein the method is a method of forming patterns.

14. The method as claimed in claim 13, further comprising performing a second heat treatment after the exposing of the metal-containing photoresist film and before the developing of the exposed metal-containing photoresist film utilizing the developer composition, wherein the second heat treatment is performed at a temperature in a range of 90° C. to 200° C.

15. The method as claimed in claim 13, wherein:
the performing of the heat treatment is performed at a temperature in a range of 80° C. to 120° C.

16. The method as claimed in claim 13, wherein the metal-containing photoresist composition comprises at least one tin-based compound selected from the group consisting of an alkyl tin oxo group, an alkyl tin carboxyl group, an alkyl tin hydroxyl group, and combinations thereof.

17. The method as claimed in claim 13, wherein:
the patterns have a pitch having a half-pitch of less than or equal to 50 nm and a line width roughness of less than or equal to 10 nm.

18. The method as claimed in claim 13, wherein:
the patterns have a thickness width in a range of 5 nm to 100 nm.

19. The method as claimed in claim 13, wherein:
the exposing of the metal-containing photoresist film is exposing the metal-containing photoresist film to light having a wavelength range of 5 nm to 150 nm.

20. The method as claimed in claim 13, wherein the number of hydrogen bonds utilized to evaluate the developer composition is determined based on molecular dynamics simulation performed with:
a molecular dynamics program comprising the Desmond module of the Materials Science Suite;
a force field comprising OPLS3e; and
simulation conditions comprising an NPT ensemble, a simulation time of 100 nanoseconds, a temperature of 500 K, and a pressure of 1 atm.
